(19) United States
(12) Patent Application Publication
(10) Pub. No.: US 2005/0082668 A1
(43) Pub. Date: Apr. 21, 2005

(54) Radio card

(75) Inventor: Masaru Murohara, Yokohama-shi (JP)

Correspondence Address: PILLSBURY WINTHROP, LLP, P.O. BOX 10500, MCLEAN, VA, 22102, US

(73) Assignee: Kabushiki Kaisha Toshiba, Tokyo (JP)

(21) Appl. No.: 10/946,349

(22) Filed: Sep. 22, 2004

(30) Foreign Application Priority Data
Sep. 25, 2003 (JP) 2003-334155

(51) Int. Cl. H01L 23/053

(52) U.S. Cl. 257/734

(57) ABSTRACT

A radio card includes a board, an LSI having a bump on one surface thereof and mounted on the board with the bump interposed therebetween, an SUS board having a rib which is bonded to the other surface of the LSI with the rib interposed therebetween and is located almost on a line being orthogonal to a surface direction of the LSI and passing through the bump, and an adhesive interposed between the SUS board and the other surface of the LSI and bonding the SUS board to the LSI.

### CROSS-REFERENCE TO RELATED APPLICATIONS

This application is based upon and claims the benefit of priority from prior Japanese Patent Application No. 2003-334155, filed Sep. 25, 2003, the entire contents of which are incorporated herein by reference.

### BACKGROUND OF THE INVENTION

1. Field of the Invention

The present invention relates to an LSI-equipped radio card.

2. Description of the Related Art

As a radio card of this kind, for example, a card as shown in FIG. 3 is known.

In FIG. 3, reference numeral 21 denotes a board. The board 21 comprises a base material 21a and an antenna pattern 21b. As the base material 21a, polyethylene terephthalate (hereinafter referred to as “PET”) having a 0.05 mm thickness is used. An aluminum foil having a 0.038 mm thickness is used for the antenna pattern 21b, and wire is formed by etching the aluminum foil.

On each of the terminals 22 of the antenna pattern 21b in the board 21, a bump 24 of an LSI 23 is mounted in a flip chip manner. The LSI 23 is electrically connected to the board 21, with an anisotropic conductive film 27 interposed therebetween.

The radio card configured as described above converts radio waves provided from the outside into electric power to operate the LSI 23, and sends back a response with remaining electric power. Thereby, the radio card performs noncontact data communications.

In the meantime, to improve the point-pressure strength and the resistance to bending stress, a reinforcing board 25 such as a SUS board is bonded to the LSI 23 by an adhesive 26 to form one unitary piece.

Further, the reinforcing board 25 is provided with projection ribs 28. The reinforcing board 25 is bonded to the LSI 23 with the ribs 28 interposed therebetween. The amount of the adhesive 26 interposed between the LSI 23 and the reinforcing board 25 is determined according to the height of the ribs 28, to maintain the thickness uniform after bonding.

However, in prior art, the bumps 24 of the PSI 23 are provided in positions distant from the ribs 28 of the reinforcing board 25 by, for example, a distance S in the surface direction of the LSI 23. Therefore, when the LSI 23 is mounted, if pressure is applied to the LSI 23 through the ribs 28 of the reinforcing board 25, the problem arises that bending stress occurs and causes a crack 29 in the LSI 23 as shown in FIG. 4.

### BRIEF SUMMARY OF THE INVENTION

The present invention has been made in consideration of the above circumstances. The object of the present invention is to provide a radio card in which no crack occurs in its LSI when the LSI is mounted.

A radio card according to an aspect of the present invention comprises: a board; an LSI having a bump on one surface thereof and mounted on the board with the bump interposed therebetween; a reinforcing member which has a projecting portion and is bonded to the other surface of the LSI with the projecting portion interposed therebetween, the projecting portion being located almost on a line, the line being orthogonal to a surface direction of the LSI and passing through the bump; and an adhesive interposed between the reinforcing member and the other surface of the LSI, and bonding the reinforcing member to the LSI.

A radio card according to another aspect of the present invention comprises: a board; an LSI having a bump on one surface thereof and a projecting portion on the other surface thereof and mounted on the board with the bump interposed therebetween, the projecting portion being located almost on a line, the line being orthogonal to a surface direction of the LSI and passing through the bump; a reinforcing member bonded to the other surface of the LSI with the projecting portion interposed therebetween; and an adhesive interposed between the reinforcing member and the LSI, and bonding the reinforcing member to the LSI.

According to aspects of the present invention, the pressure generated in mounting the LSI can be directly transmitted from projecting portions of the reinforcing member or projecting portions of the LSI to the bumps of the LSI, and occurrence of a crack in the LSI due to bending stress is prevented.

Additional advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a cross-sectional view of a radio card according to a first embodiment of the present invention.

FIG. 2 is a cross-sectional view of a radio card according to a second embodiment of the present invention.

FIG. 3 is a cross-sectional view of a conventional radio card.

FIG. 4 is a diagram illustrating the state where a crack occurs in an LSI of the conventional radio card.

### DETAILED DESCRIPTION OF THE INVENTION

The present invention is explained in detail below, with reference to embodiments shown in drawings.

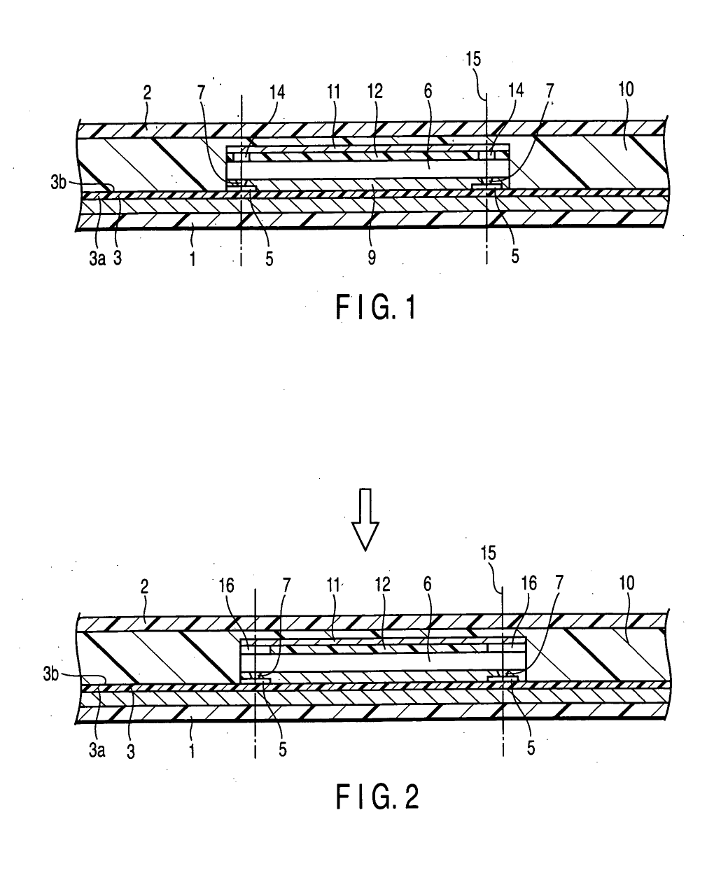

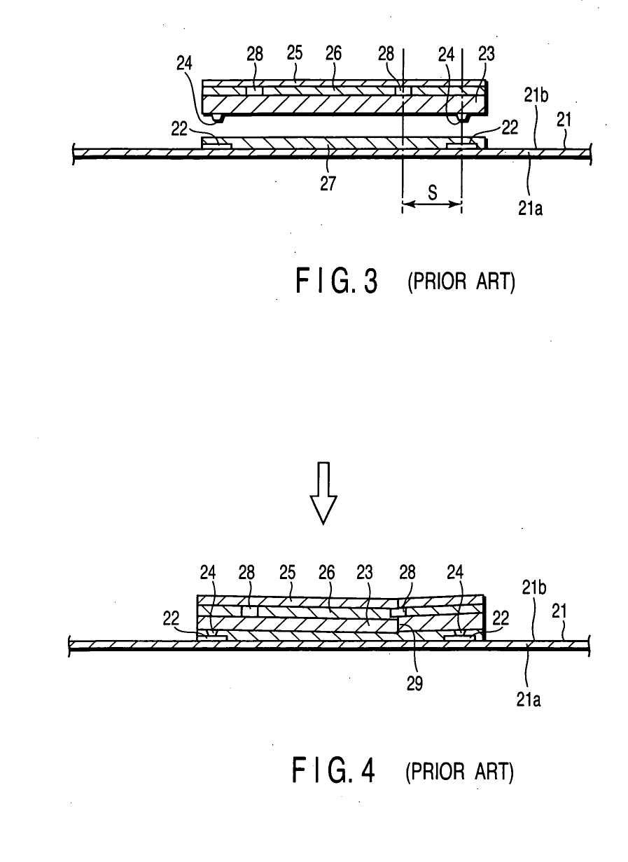

FIG. 1 is a cross-sectional view of a radio card according to a first embodiment of the present invention.

The radio card converts radio waves provided from the outside into electric power to operate an LSI, sends back a response with remaining electric power, and thereby performs noncontact data communications.

The radio card has a front sheet 1 and a back sheet 2. A board 3 is provided between the front and back sheets 1 and 2. The board 3 comprises a base material 3a and an antenna pattern 3b. As the base material 3a, polyethylene terephthalate (hereinafter referred to as “PET”) having a 0.05 mm thickness is used. An aluminum foil having a 0.038 mm thickness is used for the antenna pattern 3b, and wire is formed by etching the aluminum foil.

Bumps 7 of LSI 6 are mounted on both respective terminals 5 of the antenna pattern 3b of the board 3 in a flip-chip manner. The LSI 6 is electrically connected to the board 3 with an anisotropic conductive film 9 interposed therebetween. Further, a filler 10 is filled into the space between the front and back sheets 1 and 2.

In the meantime, an SUS board 11 serving as a reinforcing member is bonded to a back surface of the LSI 6 by adhesive 12 to form one unitary piece. The SUS board 11 has almost the same size as that of the LSI 6, and a thickness of 100 μm.

Further, ribs 14 each having a 30 μm height are formed in the four corners and the center of the SUS board 11 by etching. The height of the ribs 14 determines the space between the LSI 6 and the SUS board 11. Thereby, the amount of the adhesive 12 is determined, and the thickness of the LSI 6 with the reinforcing SUS after curing of the adhesive is determined. The ribs 14 of the SUS board 11 may be formed by pressurization or heat transformation, instead of etching. Further, the ribs 14 and the bumps 7 are formed in almost the same shape.

In the meantime, the ribs 14 of the SUS board 11 and the bumps 7 of the LSI 16 are arranged so as to be located on lines (vertical lines in FIG. 1) 15 which are orthogonal to the surface direction of the LSI 6. The ribs 14 are located above the bumps 7.

Recently, the SUS board 11 is formed with a greater thickness to enhance the reinforcing strength of the LSI 6, and the LSI 6 is thinned correspondingly. Therefore, the radio card is in the state where a crack easily occurs in the LSI 6 due to pressure occurring when the LSI is mounted.

However, since the ribs 14 of the SUS board 11 are arranged above the bumps 7 of the LSI 6 as described above, the pressure occurring in mounting the LSI is directly transmitted from the ribs 14 to the bumps 7 through the LSI 6. Therefore, no large bending stress occurs in the LSI 6, and occurrence of a crack is prevented.

FIG. 2 is a cross-sectional view of a radio card according to a second embodiment of the present invention.

In FIG. 2, the same constituent elements as those shown in the above first embodiment are denoted by the same respective reference numerals, and their explanations are omitted.

In the above first embodiment, the ribs 14 are formed on the SUS board 11. In the second embodiment, ribs 16 are formed on a back surface of the LSI 6 by etching the LSI 6. Bumps 7 have a different shape from that of the ribs 16.

Also in this embodiment, the bumps 7 and the ribs 16 are arranged so as to be located on lines 15, in the same manner as the above embodiment. Thereby, the pressure in mounting the LSI is directly transmitted from the ribs 16 to the bumps 7 via the LSI 6, and occurrence of a crack in the LSI 6 is prevented.

In the above embodiments, as long as the pressure in mounting the LSI 6 is directly transmitted to the bumps 7 through the ribs 14 or 16, the ribs 14 and 16 are not necessarily accurately located directly above the bumps 7, but may be located slightly off the lines.

Further, the present invention can be variously modified and carried out within the range of the gist of the invention as a matter of course.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A radio card comprising:
a board;
an LSI having a bump on one surface thereof, and mounted on the board with the bump interposed therebetween;
a reinforcing member which has a projecting portion and is bonded to the other surface of the LSI with the projecting portion interposed therebetween, the projecting portion being located almost on a line, the line being orthogonal to a surface direction of the LSI and passing through the bump; and
an adhesive interposed between the reinforcing member and the other surface of the LSI, and bonding the reinforcing member to the LSI.

2. A radio card according to claim 1, wherein the projecting portion of the reinforcing member is formed by etching, pressurization or heat transformation.

3. A radio card according to claim 1, wherein the bump of the LSI and the projecting portion of the reinforcing member are formed in almost the same shape, or different shapes.

4. A radio card comprising:
a board;
an LSI having a bump on one surface thereof and a projecting portion on the other surface thereof, and mounted on the board with the bump interposed therebetween, the projecting portion being located almost on a line, the line being orthogonal to a surface direction of the LSI and passing through the bump;
a reinforcing member bonded to the other surface of the LSI with the projecting portion interposed therebetween; and
an adhesive interposed between the reinforcing member and the LSI, and bonding the reinforcing member to the LSI.

5. A radio card according to claim 4, wherein the LSI has a wafer and the projecting portion is formed of the wafer.

6. A radio card according to claim 4, wherein the bump and the projecting portion of the LSI are formed in almost the same shape, or different shapes.
